(19) United States
(12) Patent Application Publication
(10) Pub. No.: US 2025/0174428 A1
(43) Pub. Date: May 29, 2025

(54) SEGMENTED ENDPOINTING FOR SAMPLE PREPARATION

(71) Applicant: FEI COMPANY, Hillsboro, OR (US)

(72) Inventors: Tomáš Onderlicka, Brno (CZ); Jaroslav Stárek, Krelov-Bruchotín (CZ); Jamie Gravell, Hillsboro, OR (US); Jaroslav Maniš, Tucapy (CZ)

(73) Assignee: FEI COMPANY, Hillsboro, OR (US)

(21) Appl. No.: 18/932,278

(22) Filed: Oct. 30, 2024

Related U.S. Application Data
(60) Provisional application No. 63/603,066, filed on Nov. 27, 2023.

(51) Int. Cl. H01J 37/22; H01J 37/26; H01J 37/28

(52) U.S. Cl. CPC H01J 37/22; H01J 37/265; H01J 37/28

(57) ABSTRACT

Segmented endpointing techniques for sample preparation are disclosed. A charged particle microscope system can be configured to remove a first layer of material from the sample by directing an ion beam toward a surface of the sample in a pattern. The pattern corresponding to a segment of the sample. After the first layer is removed, the system can remove a second layer of material from the segment such that a thickness of at least a portion of the segment is reduced. Removing the second layer can include directing the ion beam toward the portion of the sample in N patterns corresponding to N segments of the portion, obtaining an image of the surface of the sample, and stopping, based on the image, the directing of the ion beam toward a segment of the N segments.

### CROSS-REFERENCES TO RELATED APPLICATIONS

The present application claims the benefit of and priority to U.S. Provisional Application 63/603,066, filed on Nov. 27, 2023, and entitled “SEGMENTED ENDPOINTING FOR SAMPLE PREPARATION,” the entire contents of which are herein incorporated by reference in their entirety for all purposes.

### FIELD

The present disclosure is directed to charged particle microscopy. More particularly, the present disclosure describes methods and systems for sample preparation using segmented endpoints.

### BACKGROUND

Charged particle microscopy can be used to investigate and analyze samples, for example using transmission electron microscopes (TEM). To view samples with a TEM, thin lamellae are formed from the sample including various structures and other features to be imaged with the TEM. Lamellae are thin membranes that are partially transparent to electrons and are typically between 7 nm to 25 nm in thickness. Due to the small dimensions of the lamellae, careful preparation of the lamellae is required to preserve structures in the sample for imaging.

### BRIEF SUMMARY

The techniques described herein are directed to systems and methods for preparing samples for imaging using segmented endpointing. One embodiment is directed to a method including removing a first layer of material from a sample by at least directing an ion beam toward a surface of the sample in a pattern. The pattern can correspond to a segment of the sample. After the first layer is removed, a second layer of material can be removed from the segment such that a thickness of at least a portion of the segment is reduced. The method also includes that the second layer can be removed by at least: directing the ion beam toward the portion of the sample in N patterns corresponding to N segments of the portion, each of the N segments being smaller than the portion of the sample; obtaining an image of the surface of the sample, the image showing the N segments of the sample; and stopping the directing of the ion beam toward a first segment of the N segments, the stopping based on the image.

The method can also include stopping the directing of the ion beam based on the image includes comparing the image to an endpoint. The endpoint can correspond to the first segment of the sample.

In an example, the sample includes a plurality of structures, the image includes a view of a first structure of the plurality of structures located within the first segment, the endpoint is characterized by a desired structure. In this example, the method can also include comparing the image to the endpoint includes comparing the view of the first structure of the plurality of structures to the desired structure of the endpoint.

The method can also include continuing directing the ion beam toward a remaining portion of the sample away from the first segment, the remaining portion corresponding to remaining segments of the N segments exclusive of the first segment; obtaining an additional image of the surface of the sample, the additional image showing the remaining segments of the sample; and stopping the directing of the ion beam toward a second segment of the remaining segments, the stopping based on comparing the additional image to an additional endpoint.

In an example, the additional endpoint can be different from the endpoint.

The method can also include removing, after the second layer is removed, a third layer of material from the segment such that the thickness of an additional portion of the segment is further reduced. Removing the third layer can include: directing the ion beam toward the additional portion in M patterns corresponding to M segments of the additional portion, M being greater than N, and each of the M segments being smaller than each of the N segments; obtaining an additional image of the surface of the sample, the additional image showing the M segments of the sample; and stopping the directing of the ion beam toward a second segment of the M segments, the stopping based on the additional image.

The method can also include removing the first layer of material occurs with the ion beam set to a first energy, and removing the second layer of material using the N patterns occurs with the ion beam set to a second energy different from the first energy.

In several examples, N can be based in part on the thickness of the sample after the removal of the first layer of material, a width of the portion of the segment, and/or a material of the sample. In some examples, N can be a predetermined number.

In an example, the N segments can be adjacent and non-overlapping. In another example, a first segment of the N segments can overlap with a portion of a second segment of the N segments. In another example, each of the N segments can be the same width. In yet another example, a first segment of the N segments and a final segment of the N segments can each include a corresponding extended width characterized by (i) a default width of the N patterns and (ii) a beam width of the ion beam.

Another embodiment is directed to a system, for example a dual beam charged particle microscope system. The system can include a vacuum chamber, a sample stage disposed in the vacuum chamber and configured to receive a sample in the vacuum chamber, an ion beam column configured to provide an ion beam into the vacuum chamber, and a controller. The controller can include one or more processors and one or more memories that store computer-executable instructions that, when executed by the one or more processors, cause the system to perform the method described above.

The system can also include an electron beam column configured to provide an electron beam into the vacuum chamber, and wherein obtaining the image comprises imaging the surface of the sample with the electron beam.

Another embodiment is directed to a non-transitory computer-readable medium storing instruction that, when executed by a processor of a charged particle microscopy system, cause the charged particle microscopy system to thin a sample to a first thickness by at least using an ion beam to remove a first layer of material from a surface of the sample. The removal of the first layer of material can be stopped based on an image of the surface of the sample. The instructions can also cause the charged particle microscopy system to thin the sample by at least using the ion beam to remove a second layer of material from each of N segments of the surface of the sample. The removal of the second layer of material can be stopped in each of the N segments based on additional images of the surface of the sample corresponding to each of the N segments.

In an example, the removal of the first layer of material can be stopped based on comparing the image to an endpoint corresponding to the surface of the sample.

In an example, the removal of the second layer of material from each of the N segments can be stopped based on comparing at least one of the additional images of the surface to a corresponding endpoint for each segment of the N segments.

In an example, after removing the second layer of material from each of the N segments, each of the N segments can have a segment thickness.

In an example, the segment thickness for each of the N segments can be different after removal of the second layer of material from each of the N segments.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram of an example dual beam system for preparing samples using segmented endpointing, according to some embodiments.

FIG. 2A is a diagram illustrating a view of a sample for preparation using a dual beam charged particle microscope, according to some embodiments.

FIG. 2B is a diagram illustrating another view of the sample of FIG. 2A including various structures of the sample, according to some embodiments.

FIG. 3A is an image of a cutface of a sample showing a plurality of structures, according to some embodiments.

FIG. 3B is a diagram of the cutface of FIG. 3A, identifying various structures of the sample, according to some embodiments.

FIG. 4A is a diagram illustrating milling a sample using one pattern for one segment, according to some embodiments.

FIG. 4B is a diagram illustrating the cutface of the sample of FIG. 4A with the milling stopped based on a single endpoint, according to some embodiments.

FIG. 5A is a diagram illustrating milling a sample using N patterns for N segments, according to some embodiments.

FIG. 5B is a diagram illustrating the cutface of the sample of FIG. 5A with the milling stopped in segments according to N endpoints, according to some embodiments.

FIG. 6 is a flow diagram of an example process for operating a dual beam charged particle microscope system to prepare a sample using a plurality of endpoints, according to some embodiments.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While exemplary embodiments have been illustrated and described, it will be appreciated that various changes can be made therein without departing from the spirit and scope of the disclosure.

Charged particle microscopy is used in various industries, including the semiconductor industry, to analyze micrometer and nanometer scale structures. For example, semiconductor devices can include nanometer scale transistors densely arranged within a silicon wafer. Images obtained with charged particle microscopy can be used to improve process control, evaluate the quality of fabricated devices, and improve yields. In the case of semiconductor devices, objects like field effect transistors (FETs) may be formed within the larger silicon wafer and adjacent to several other structures, including other FETs, vias, diode junctions, and the like. Because of the extremely small scale and dense packing of the elements, imaging of these elements can be improved by careful preparation of the sample.

Imaging samples with a charged particle microscope can include using a transmission electron microscope (TEM), a scanning electron microscope (SEM), a scanning TEM (STEM), or related techniques. To image samples using these techniques, a lamella is formed and removed from the larger substrate (e.g., the silicon wafer). The lamella can include the structures forming the devices (e.g., FETs). The lamella can be formed and removed using a dual-beam charged particle microscope system, which typically includes a focused ion beam (FIB) and a scanning electron microscope (SEM). During the lamella formation process, the FIB is used to remove material from the substrate, leaving the lamella as a portion of the remaining material, while the SEM is used for imaging to guide the FIB process. This process has become conventional in many industries, not just the semiconductor industry, and is used to image and analyze almost any type of micron or nanometer scale structure buried within a surrounding substrate.

Once a lamella has been removed from the surrounding material, additional milling with the FIB can be performed to further thin the lamella. For example, an initial lamella sample from a substrate can be formed with a thickness on the order of 1 μm. Milling the lamella in one or more steps with various ion beam energies (e.g., 30 kV, 2 kV) can reduce a portion of the initial lamella sample to thicknesses of less than 100 nm, including, for example, lamellae having thicknesses of 50 nm, 20 nm, 15 nm, and less than 10 nm. By thinning the lamella, image resolution of structures within the lamella can be improved.

In the case of semiconductor devices, the continued development of smaller scale structures that are more closely packed within their substrate has led to challenges in forming suitable lamellas for imaging purposes. Small scale structures may be arranged in several layers within the same substrate, such that structures of layers in front of or behind the structure of interest can obscure or occlude the structure of interest during imaging. For example, a lamella can include a line of transistor elements (e.g., semiconductor channel fins) spaced apart from another line of transistor elements by 50 nm. To image only one line of transistor elements, the lamella can be thinned to remove the material containing the other line of transistor elements.

In many cases, the structures of interest should be at or near the surface of the lamella. Thus, milling the lamella to a suitable thickness can include removing material from the lamella until the structures of interest are at or near the surface of the lamella, as determined by imaging the surface of the lamella. Because the milling process can remove material from the structures of interest, careful control of the end point of the FIB milling is desired. This control is typically achieved by imaging the surface of the sample during milling to identify structures of interest and then comparing the shapes (e.g., dimensions like width, pitch/separation, absence of artifacts/occlusions, etc.) of the structures to the expected shape of the structures. When the imaged structures match the expected shape of the desired structures for the sample, the milling process can be stopped. As used herein, the term “endpoint” or “endpointer” can refer to the features or shape that characterizes the desired surface of the lamella, while the term “endpointing” can refer to the technique of controlling the milling of a sample based on one or more endpoints. Thus, milling of the lamella with the FIB can be stopped when the surface, or a portion thereof, matches an endpoint as determined by image analysis. Typical endpointing stops the milling of a lamella based on a portion of the lamella surface (e.g., the center of the lamella surface) matching an endpoint. Specific details about using a single endpoint to determine the depth of milling of a sample may be found in U.S. Patent Application Publication No. 2023/0307209, the contents of which are incorporated herein by reference in their entirety for all purposes.

When milling a lamella to a very small thickness (e.g., <15 nm), the lamella can exhibit warping or bending across its length, transverse to the direction of milling. This warping can cause portions of the lamella cutface to be slightly closer to or slightly further from the beam axis of the FIB than other portions of the lamella cutface. Thus, during milling with the FIB using an endpoint for a central portion of the lamella, other portions of the lamella may have too much or too little material removed. The result can be a lamella with device structures at the surface that are damaged or distorted even though the endpoint was reached for the central portion. Conventionally, operators of the dual beam system can manually correct for the warping of the lamella by adjusting the sample rotation during separate milling steps. However, such manual operations rely on operators having substantial experience making fine, manual adjustments of the dual beam system parameters, are substantially slower than automated endpointing, and typically do not yield consistent results from sample to sample.

To avoid the overmilling/undermilling effects for very thin lamellae when using automated endpointing in a dual beam system, a segmented endpointing technique can be employed. After thinning the lamella to a first thickness (e.g., 20 nm) using a single endpoint, the lamella can be thinned to a second thickness (e.g., 10 nm) using a number N of endpoints, each corresponding to a different portion of the lamella. For example, the lamella can be divided into five segments. The FIB can be configured to remove material from each of those five segments in a pattern corresponding to each segment. As material is removed from each segment, the dual beam system can image the surface of the lamella. Once the image of a segment matches the endpoint for that segment, the milling for that segment can be stopped, while the milling proceeds for the remaining four segments. As each segment reaches its endpoint, the milling stops for each segment until every segment has reached its endpoint. Thus, segments for which the lamella warping would have caused “overmilling” can reach their endpoint sooner than segments for which the lamella warping would have caused “undermilling.”

By using segmented endpointing, numerous advantages are obtained over conventional sample preparation techniques. For example, segmented endpointing can be automated for use as part of overall sample preparation. Lamellae can be thinned in one or more initial steps at a first FIB energy using a single endpoint. Then, for the final thinning, segmented endpointing can be used at a second FIB energy to remove material for different segments without the need for manual adjustments or corrections, resulting in improved samples at very small thicknesses (e.g., <10 nm). As another example, different endpoints may be used for different segments. For instance, the region of interest of the lamella may include structures for different types of devices in different locations. A single endpoint may not be suitable for controlling the milling of the lamella in locations containing the different devices. Thus, segmented endpointing can allow for the correct control of the FIB milling at segments including the different devices. As yet another example, different numbers of endpoints (e.g., 3, 5, 7) can be used for different milling steps on the same lamella, allowing for finer control of the milling for each step of the thinning process. Moreover, because the multiple segments can be milled in parallel, the segmented endpointing does not significantly increase the milling time for the lamella, allowing for more accurate samples at the same operational throughput.

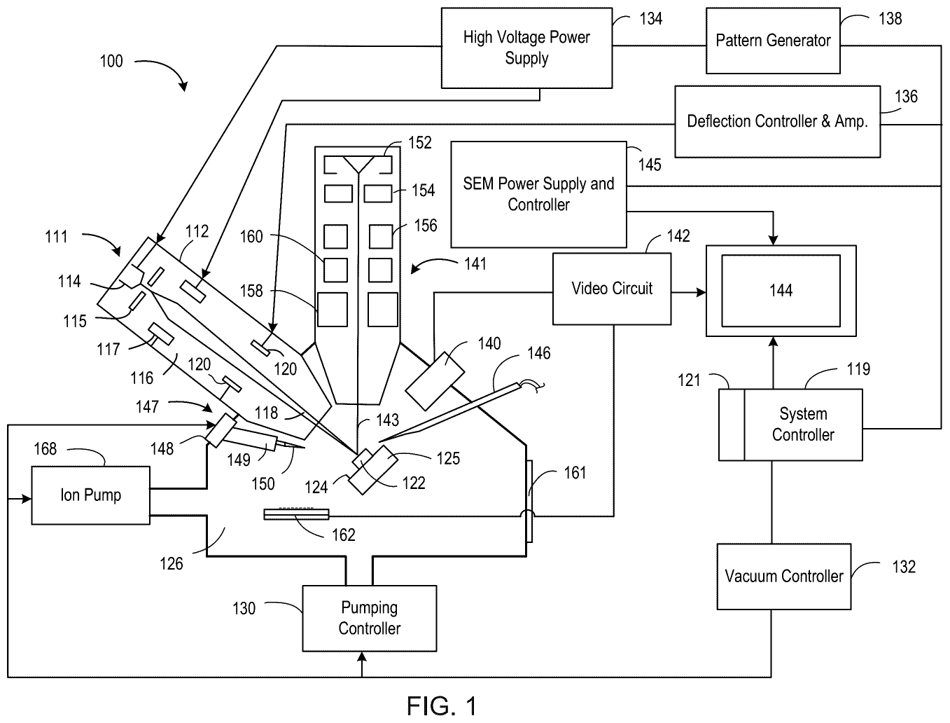

FIG. 1 is a schematic diagram of an example dual beam system 100 for preparing samples using segmented endpointing, according to some embodiments. System 100 may be used to implement the segmented endpointing techniques discussed herein. In some embodiments, the system 100 will perform sample milling and endpoint detection, including segmented endpoint detection. However, in other embodiments, the milling algorithms may be performed by a computing system coupled to system 100, such as at a user's desk or a cloud based computing system. In either embodiment, the determination of milling endpoint may be provided to system 100 for automatic milling control to ensure that the surface of the thinned lamella is correctly obtained. While an example of suitable hardware is provided below, the invention is not limited to being implemented in any particular type of hardware.

An SEM 141, along with power supply and control unit 145, is provided with the dual beam system 100. An electron beam 143 is emitted from a cathode 152 by applying voltage between cathode 152 and an anode 154. Electron beam 143 is focused to a fine spot by means of a condensing lens 156 and an objective lens 158. Electron beam 143 is scanned two-dimensionally on the specimen by means of a deflector 160. Operation of condensing lens 156, objective lens 158, and deflector 160 is controlled by power supply and control unit 145.

Electron beam 143 can be focused onto substrate 122, which is on stage 125 within lower chamber 126. Substrate 122 may be located on a surface of stage 125 or on TEM sample holder 124, which extends from the surface of stage 125.

When the electrons in the electron beam strike substrate 122, secondary electrons are emitted. These secondary electrons are detected by secondary electron detector 140. In some embodiments, STEM detector 162, located beneath the TEM sample holder 124 and the stage 125 collects electrons that are transmitted through the sample mounted on the TEM sample holder.

System 100 also includes FIB system 111 which comprises an evacuated chamber having an ion column 112 within which are located an ion source 114 and focusing components 116 including extractor electrodes and an electrostatic optical system. The axis of focusing column 116 may be tilted, 52 degrees for example, from the axis of the electron column 141. The ion column 112 includes an ion source 114, an extraction electrode 115, a focusing element 117, deflection elements 120, which operate in concert to form focused ion beam 118. Focused ion beam 118 passes from ion source 114 through focusing components 116 and between electrostatic deflection means schematically indicated at 120 toward substrate 122, which may comprise, for example, a semiconductor wafer positioned on movable stage 125 within lower chamber 126. In some embodiments, a sample may be located on TEM grid holder 124, where the sample may be a chunk extracted from substrate 122. The chunk may then undergo further processing with the FIB to form a final lamella of a desired thickness in accordance with techniques disclosed herein.

Stage 125 can move in a horizontal plane (X and Y axes) and vertically (Z axis). Stage 125 can also tilt and rotate about the Z axis. In some embodiments, a separate TEM sample stage 124 can be used. Such a TEM sample stage will also preferably be moveable in the X, Y, and Z axes as well as tiltable and rotatable. In some embodiments, the tilting of the stage 125/TEM holder 124 may be in and out of the plane of the ion beam 118, and the rotating of the stage is around the ion beam 118. As used herein to illustrate the disclosed techniques, such relationship will be maintained when discussing rotation and tilting of a sample. Of course, the opposite definitions could be used but would still fall within the contours of the present disclosure.

A door 161 is opened for inserting substrate 122 onto stage 125. Depending on the tilt of the stage 124/125, the Z axis will be in the direction of the optical axis of the relevant column. For example, during a data gathering stage of the disclosed techniques, the Z axis will be in the direction, e.g., parallel with, the FIB optical axis as indicated by the ion beam 118. In such a coordinate system, the X and Y axis will be referenced from the Z-axis. For example, the X-axis may be in and out of the page showing FIG. 1, whereas the Y-axis will be in the page, all while all three axes maintain their perpendicular nature to one another.

An ion pump 168 is employed for evacuating neck portion. The chamber 126 is evacuated with turbomolecular and mechanical pumping system 130 under the control of vacuum controller 132. The vacuum system provides within chamber 126 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

The high voltage power supply provides an appropriate acceleration voltage to electrodes in focusing column 116 for energizing and focusing ion beam 118. When it strikes substrate 122, material is sputtered, that is physically ejected, from the sample. Alternatively, ion beam 118 can decompose a precursor gas to deposit a material.

High voltage power supply 134 is connected to ion source 114 as well as to appropriate electrodes in ion beam focusing components 116 for forming an approximately 1 keV to 60 keV ion beam 118 and directing the same toward a sample. Deflection controller and amplifier 136, operated in accordance with a prescribed pattern provided by pattern generator 138, is coupled to deflection plates 120 whereby ion beam 118 may be controlled manually or automatically to trace out a corresponding pattern on the upper surface of substrate 122. In some systems the deflection plates are placed before the final lens, as is well known in the art. Beam blanking electrodes (not shown) within ion beam focusing column 116 cause ion beam 118 to impact onto blanking aperture (not shown) instead of substrate 122 when a blanking controller (not shown) applies a blanking voltage to the blanking electrode.

The ion source 114 typically provides an ion beam based on the type of ion source. In some embodiments, the ion source 114 is a liquid metal ion source that can provide a gallium ion beam, for example. In other embodiments, the ion source 114 may be plasma-type ion source that can deliver a number of different ion species, such as oxygen, xenon, and nitrogen, to name a few. The ion source 114 typically is capable of being focused into a sub one-tenth micrometer wide beam at substrate 122 or TEM grid holder 124 for either modifying the substrate 122 by ion milling, ion-induced etching, material deposition, or for the purpose of imaging the substrate 122.

A charged particle detector 140, such as an Everhart-Thornley detector or multi-channel plate, used for detecting secondary ion or electron emission is connected to a video circuit 142 that supplies drive signals to video monitor 144 and receiving deflection signals from a system controller 119. The location of charged particle detector 140 within lower chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

A micromanipulator 147 can precisely move objects within the vacuum chamber. Micromanipulator 147 may comprise precision electric motors 148 positioned outside the vacuum chamber to provide X, Y, Z, and theta control of a portion 149 positioned within the vacuum chamber. The micromanipulator 147 can be fitted with different end effectors for manipulating small objects. In the embodiments described herein, the end effector is a thin probe 150.

A gas delivery system 146 extends into lower chamber 126 for introducing and directing a gaseous vapor toward substrate 122. For example, iodine can be delivered to enhance etching, or a metal organic compound can be delivered to deposit a metal.

System controller 119 controls the operations of the various parts of dual beam system 110. Through system controller 119, a user can cause ion beam 118 or electron beam 143 to be scanned in a desired manner through commands entered into a conventional user interface (not shown). Alternatively, system controller 119 may control dual beam system 110 in accordance with programmed instructions stored in a memory 121. In some embodiments, dual beam system 110 incorporates image recognition software to automatically identify regions of interest, and then the system can manually or automatically extract samples in accordance with the invention. For example, the system could automatically locate similar features on semiconductor wafers including multiple devices, and take samples of those features on different (or the same) devices.

In operation in accordance with the techniques disclosed herein, system 100 images a working surface (e.g., a cutface) of a sample 122, the sample 122 being a chunk previously removed from a substrate. The chunk, which may be about 1 μm in thickness, may be attached to TEM holder 124 in this example. As used herein, the working surface is a side surface of the chunk, the chunk needing to be thinned into a final lamella thickness. The sample 122 may include structures that should be aligned/oriented to the ion beam 118, such as in terms of rotation and/or tilt, so that during the final lamella formation, structures that require subsequent imaging are not removed. The image of the newly exposed surface can be acquired using either the electron column 141 or the FIB 111.

Layers of sample 122 can be removed from the working surface. The removal of a layer may be performed using FIB milling or ion induced etching using a gas precursor. Layers can be removed in smaller “slices” according to certain embodiments, in which slices of about 1 nm to 5 nm are removed sequentially. After the slice is removed, the newly exposed surface is imaged. The process of image acquisition and slice removal may be repeated for 25, 50, 75, or 100 times, but any other number of slices are contemplated herein. The working surface of the lamella can show structures, such as lines of devices including FETs, which are desired to be imaged and/or analyzed.

The removal of a layer of material from the sample 122 can be done by directing the FIB 111 toward a portion of the sample 122 in a pattern. For example, the ion beam may raster over the surface of the sample 122 in the portion, removing the desired layer. As described in more detail below, the system controller 119 can be configured to direct the ion beam over multiple portions of the sample 122 in a pattern (e.g., a raster pattern) corresponding to each portion. For example, the sample 122 can be divided into N segments, and the ion beam directed over each segment in a raster. The layer of material can then be removed from the sample 122 in each segment in sequence or in parallel. In some examples, the FIB 111 can raster more quickly at one portion of the surface of the sample 122. At another portion of the surface of the sample 122, the FIB 111 can raster more slowly. In some examples, for a raster pattern, the FIB 111 can have a different dwell time at each point in the raster pattern. The FIB 111 can therefore remove more material at points in the pattern at which the beam dwells longer. The images of the working surface as the material is removed can be used to determine the endpoint of the milling process with the FIB 111.

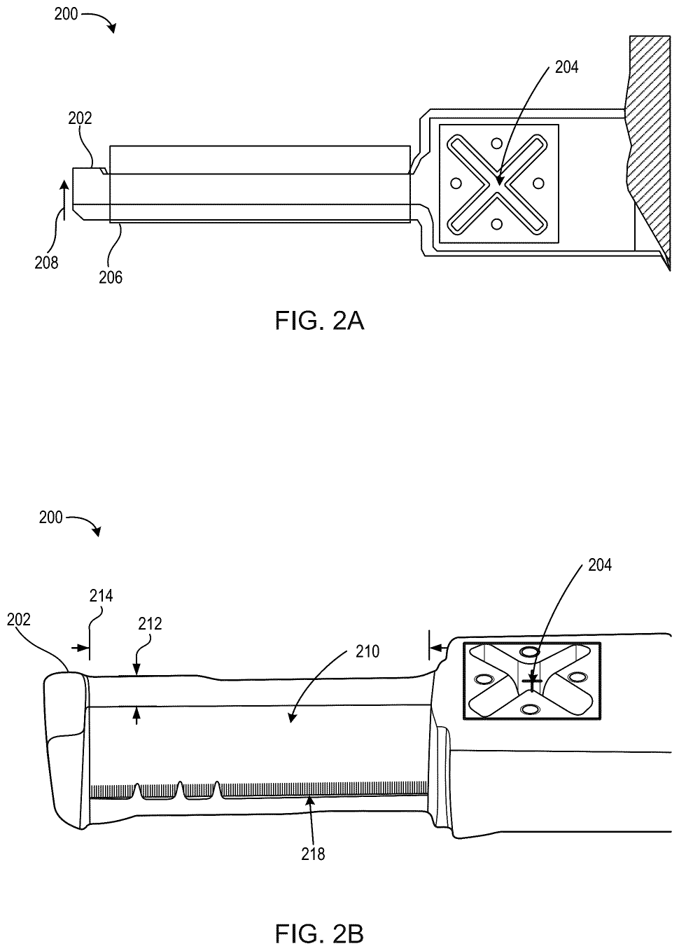

FIG. 2A is a diagram illustrating a view of a sample 200 for preparation using a dual beam charged particle microscope, according to some embodiments. The dual beam charged particle microscope can be an example of the system 100 described above with respect to FIG. 1.

The view depicted in FIG. 2A shows the “top” view of a lamella 202 formed from the sample 200 via an initial formation technique, for example a cut and lift out technique. The portion of the sample 200 at the right includes a fiducial 204 used to help guide the initial formation of the lamella 202. The material of the sample 200 near the fiducial 204 is typically not of interest in the analysis and forms a structural component of the lamella 202 for handling in the dual beam charged particle microscope. For example, the sample 200 may be attached to TEM holder 124 of FIG. 1 via material to the right of the fiducial 204.

The lamella 202 can be thinned via FIB milling. During thinning, an ion beam may be directed toward a portion 206 of the lamella 202. The portion 206 may include a central region of the lamella 202 that does not include the outer edge of the sample 200. Thus, during thinning, the outer edge of the sample 200 may not be thinned. The thinning of the lamella 202 may proceed in the direction 208 indicated by the arrow in FIG. 2A. Thus, layers of material from the sample 200 from the “bottom” edge of the portion 206. Because the ion beam may be aligned substantially parallel to the working surface of the lamella 202, the ion beam may be directed into/out from the page with respect to the view shown in FIG. 2A. In some embodiments, the direction 208 of the thinning may be reversed depending on the type of sample 200 and the milling techniques employed (e.g., backside thinning).

Thinning of the lamella 202 can proceed in several steps in which a layer of material is removed at each step. For example, a first layer of material can be removed from the lamella 202 within the portion 206 shown in FIG. 2A. Subsequently, a second layer (or third, or suitable number of additional layers) can be removed from an additional portion of the lamella 202. The energy of the ion beam can be different for the removal of each layer. For example, a first layer can be removed using a first energy of the ion beam (e.g., 30 kV) while a second layer can be removed using a second energy of the ion beam (e.g., 2 kV). The additional portion of the lamella 202 can be located in a central region of the lamella 202 smaller than the portion 206. The result of the sequential thinning operations can result in a “stair-step” pattern of thinner regions of the lamella with a central portion thinned to the desired thickness.

FIG. 2B is a diagram illustrating another view of the sample 200 of FIG. 2A including structures 218 of the sample 200, according to some embodiments. With respect to the view of FIG. 2A, FIG. 2B shows the cutface 210 of the lamella 202 on the side defined by the direction 208.

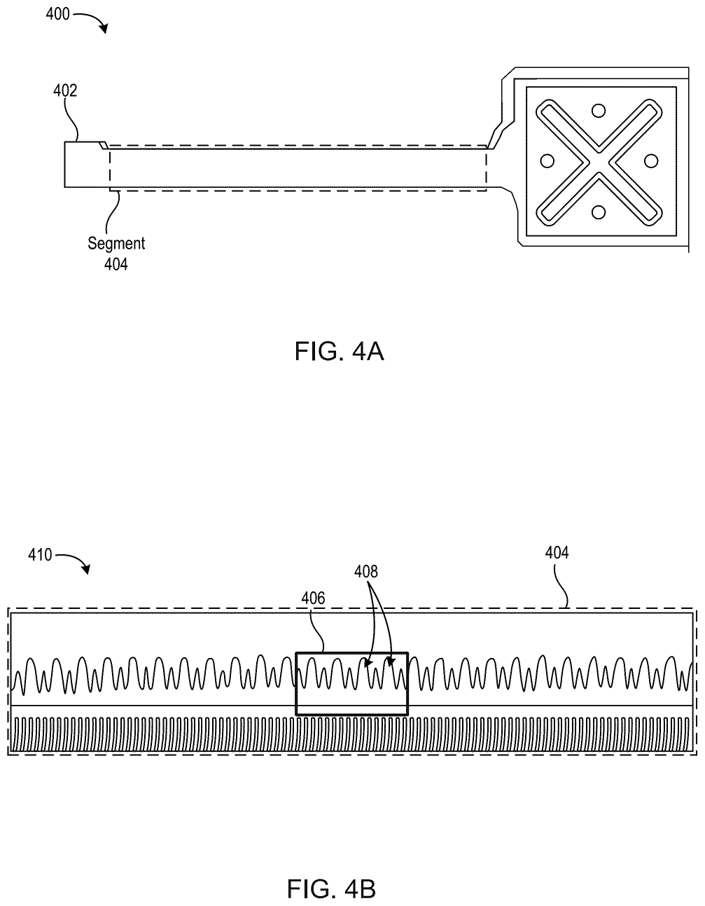

For a given sample 200, the lamella 202 can have a thickness 212 and a length 214 defined in the direction transverse to the direction 208 and the thickness 212. The thinning operations can be configured to reduce the thickness 212 to a desired thickness. As described briefly above, the initial thickness 212 of a lamella 202 after cut and lift out can be on the order of 1 μm, while the length of the lamella may be about 3 μm or greater. The lamella 202 can be thinned by removing layers of material until the thickness 212 is about 100 nm. This first thinning operation can be done using a single endpoint for the lamella 202 (described in more detail below with respect to FIGS. 4A and 4B). The lamella 202 can then be thinned further by removing additional layers of material until the thickness 212 is less than about 15 nm (e.g., 10 nm). The additional thinning operation can be done using segmented endpointing with multiple segments for milling the lamella 202, each having a corresponding endpoint. As the lamella 202 is thinned, it may exhibit a warping or bending in directions transverse to its length 214. For example, a lamella 202 of thickness less than about 100 nm may bend slightly in the direction 208 of the thinning, so that the left edge of the lamella 202 (with respect to the view of FIG. 2B) is displaced further in the direction 208 than the right edge of the lamella 202.

The sample 200 can include multiple devices or other structures of interest. The devices can be FETs (e.g., FinFETS) or other semiconductor devices (e.g., power transistors, etc.). Portions of the devices can appear at the working surface of the sample 200 as a variety of structures. As depicted in FIG. 2B, various structures, including structures 218, can be seen at the cutface 210 of lamella 202. The manufacturing of the devices typically results in a line of repeating device elements visible on the cutface 210. For example, the channel structures of FETs and the associated gate fins and oxide layers can appear as repeating small-scale structures 218. Larger scale structures (e.g., vias) can also appear at the cutface 210. Within the sample 200, additional device lines may be formed parallel to the devices shown at the cutface 210 but deeper within the sample volume. Thus, a device line with structures similar to structures 218 may be located behind the devices visible at the cutface 210. As the lamella 202 is thinned, the material of the devices at the surface can be removed, revealing the devices and associated structures deeper within the sample 200.

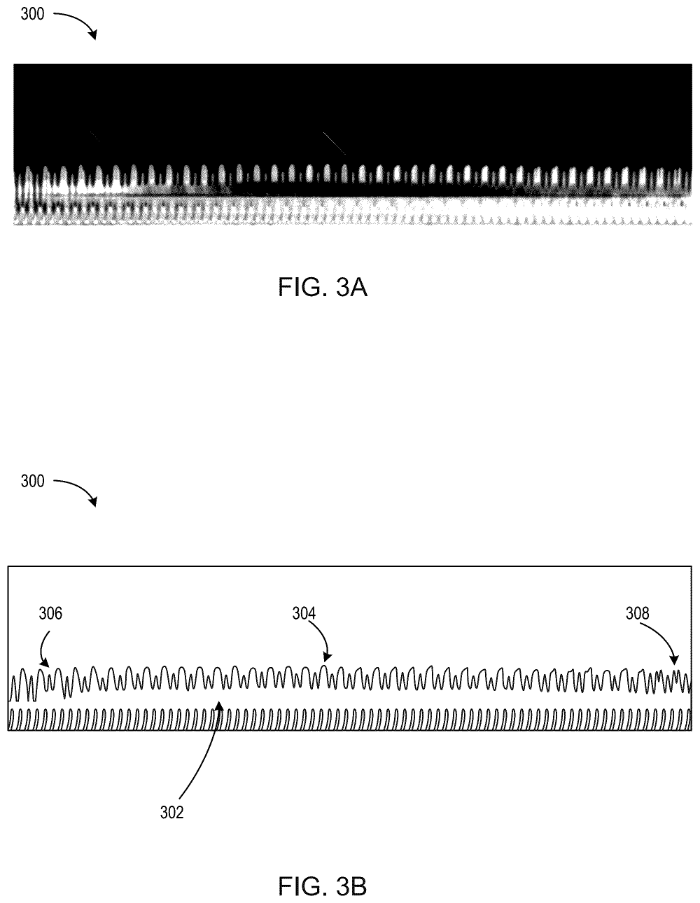

FIG. 3A is an image of a cutface 300 of a sample showing a plurality of structures, according to some embodiments. The image may be obtained from a lamella (e.g., lamella 202 of FIG. 2) using the electron beam of a dual beam charged particle microscope, for example the system 100 of FIG. 1. In some embodiments, the ion beam may be used for imaging the cutface 300 of the sample. The lamella shown in FIG. 3A has been thinned to a thickness of less than about 100 nm using a single endpoint. As shown in FIG. 3A, the cutface 300 can include a line of structures associated with a plurality of semiconductor devices. For example, the line of structures may be the fins of a FinFET.

FIG. 3B is a diagram of the cutface 300 of FIG. 3A, identifying various structures 302 of the sample, according to some embodiments. The structures 302 can be characterized by repeated “peaks” for a line of similar devices along the length of the lamella. Visible in both the diagram of FIG. 3B and the image of FIG. 3A are structures 304 at the center of the lamella, and structures 306 and structures 308 near the edges of the lamella. The “peaks” of the structures 306 and structures 308 are doubled, indicating the imaging of device structures in front of and/or behind the device line associated with the structures 304. Such distortion of the image for the structures 306 and 308 indicates that the thinning process at the edges of the lamella either removed too much or too little material, so that the structures 306 and structure 308 include portions of the device line corresponding to structures 304 as well as a device line in front of/behind the device line of interest in the lamella. In addition to the distorted “peaks” shown in FIG. 3B, other distortions can include occlusions of features of interest in the sample by features closer to the surface. For instance, in the example of a FET, the inaccuracy of the milling endpoint at the edges of the lamella can be caused by the warping of the lamella along its length.

FIG. 4A is a diagram illustrating milling a sample 400 using one pattern, according to some embodiments. The sample may be an example of the sample 200 described above with respect to FIG. 2. The sample 400 can include a lamella 402 to be thinned. The thinning can occur in a segment 404 of the of the lamella 402 using an ion beam of a dual beam charged particle system (e.g., system 100 of FIG. 1).

FIG. 4B is a diagram illustrating the cutface 410 of the sample 400 of FIG. 4A with the milling stopped based on a single endpoint 406, according to some embodiments. During the thinning operation, the ion beam can be configured to remove a layer of material from the lamella 402 in a pattern over the segment 404.

As the material in the layer is removed, images of the cutface 410 can be obtained showing one or more structures of interest within the sample 400. As shown in FIG. 4B, the structures 408 can be repeated “peaks” of device features, for example, gate fins of FETs in a device line. The endpoint 406 can be a representation of expected structures in the device line and may be characterized by one or more parameters of the structures including dimensions (e.g., width, height), pitch (e.g., separation from one feature to the next), shape (e.g., square or “rounded” profile), and the like. For the example of a line of FinFETs, the structures may be the repeated fins separated by a characteristic pitch. The endpoint 406 can then define the expected dimensions, shape, pitch, or other parameters of the devices of interest in the lamella. Comparing the endpoint 406 to the image can include image correlation techniques, for example, cross correlation, sum of squared differences, mutual information, and the like.

The dual beam charged particle microscope can be configured to automatically stop the milling process when the structures 408 visible in an image of the cutface 410 of the lamella 402 match the endpoint 406. For example, as material is removed, the devices in the sample 400 may be visible at the cutface 410. The dual beam charged particle microscope can be configured to obtain an image of the cutface 410 including the structures 408. The dual beam charged particle microscope can then compare the image to the endpoint 406. If the structures 408 match the expected structures in the endpoint 406, then the dual beam charged particle microscope can stop milling. The endpoint 406 can correspond to a small portion of the devices in the sample. For example, the endpoint 406 may correspond to a central portion of the lamella 402. Comparing the image of the cutface 410 to the endpoint 406 can occur prior to or simultaneously with the removal of a subsequent layer of material from the sample 400. For example, after removing a layer of material from the sample 400, the image of the cutface 410 can be acquired by the dual beam charged particle microscope. While the dual beam charged particle microscope compares the image of the cutface 410 to the endpoint 406, a second layer of material can be removed. In this way, the initial milling of the sample 400 can be done more quickly, since the endpoint comparison need not be completed before beginning additional milling of the sample 400. As milling depth (e.g., sample thickness) approaches the endpoint, then the dual beam charged particle microscope system can be configured to remove subsequent layers from the sample 400 after the endpoint comparison is completed.

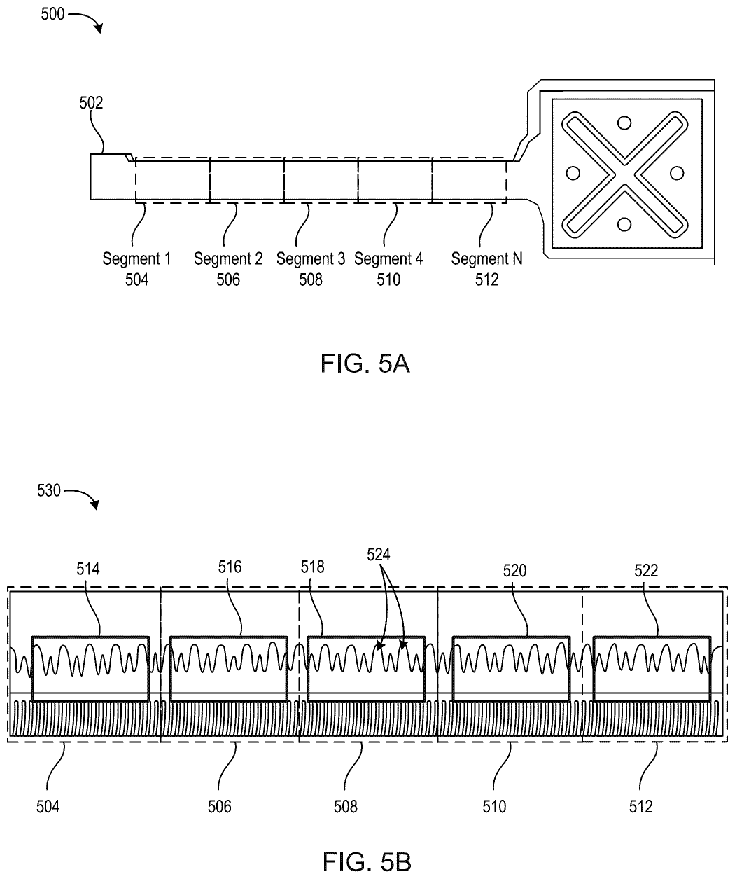

FIG. 4B shows endpointing using a single segment 404 and single endpoint 406. Such single segment endpointing can be used for initial thinning operations on the lamella 402 when the thickness of the lamella 402 is large enough (e.g., greater than about 100 nm) to not be susceptible to warping. The single segment endpointing can be used in conjunction with segmented endpointing described below with respect to FIGS. 5A and 5B.

FIG. 5A is a diagram illustrating milling a sample 500 using N patterns for N segments 504-512, according to some embodiments. The sample 500 may be an example of sample 200 of FIG. 2. In some embodiments, sample 500 may be the same as sample 400 of FIGS. 4A and 4B after an initial thinning operation using a single segment and single endpoint. As shown in FIG. 5A, a portion of the lamella 502 can be divided into N segments (e.g., five segments), including segment 1 504, segment 2 506, segment 3 508, segment 4 510, and segment N 512. A dual beam charged particle microscope (e.g., system 100 of FIG. 1) can be configured to direct an ion beam at the lamella 502 in a pattern for each of the segments 504-512. For example, the ion beam can be configured to raster over each segment 504-512 to remove material from the lamella in each segment. The ion beam can be configured to remove the material from the segments 504-512 in parallel, so that a portion of the layer of material is removed from segment 1 504, then a portion of the layer of material from segment 2 506, and so on. In some embodiments, the pattern of the ion beam for each segment can be the same or different as the pattern of the ion beam for the other segments.

FIG. 5B is a diagram illustrating the cutface 530 of the sample of FIG. 5A with the milling stopped in segments 504-512 according to N endpoints 514-522, according to some embodiments. As material is removed from the lamella 502, images of the cutface 530 can be obtained by the dual beam charged particle microscope. Each image can include the portions of the lamella 502 corresponding to the segments 504-512, showing the device structures within that portion of the lamella 502. For example, segment 508 can include structures 524. Each segment 504-512 can have a corresponding endpoint 514-522. For instance, segment 1 504 can correspond to endpoint 514, segment 2 506 can correspond to endpoint 516, and so on. The dual beam charged particle microscope can be configured to compare the images of the segments 504-512 to the endpoints 514-522 to control and stop the milling process. Each of endpoints 514-522 can be compared to a central portion of the corresponding segments 504-512. The location within each segment for comparison with the endpoint can vary. For example, the endpoint can be compared to a portion of the bottom of the segment.

The milling of each segment can be controlled separately to achieve the appropriate milling endpoint for the segment. When a segment reaches the desired end point (based on the comparison of an image of the segment with the corresponding endpoint), the pattern of the ion beam in that segment can be stopped, while the ion beam continues to remove material from the other segments. For example, the dual beam charged particle microscope can obtain an image of the cutface 530 including segment 3 508 and showing structures 524. When the structures 524 match the expected structures in the corresponding endpoint 518, the milling of segment 3 508 can be stopped, while the milling of segment 1 504, segment 2 506, segment 4 510, and segment N can continue. Thus, once a segment of the lamella 502 is milled to the desired thickness based on a comparison of an image of the segment with the corresponding endpoint, the milling of that segment can stop.

In some embodiments, the milling of each segment can be controlled separately by controlling the rate of milling within each segment. For example, the pattern and/or beam parameters for milling in one segment can be different from the pattern and/or beam parameters for milling in another segment. Such segment to segment variation can result in the milling rate (e.g., the rate of removal of the layer of material) for one segment being faster or slower than the milling rate of another segment along the sample face. In addition, the thickness of the sample within each segment once the endpoint is reached may be different. For example, the feature of interest that characterizes the endpoint of one segment (e.g., endpoint 514 of segment 1 504 of FIG. 5B) may be at a different depth in the sample than the feature of interest that characterizes the endpoint of a different segment (e.g., endpoint 518 of segment 3 508 of FIG. 5B). One exemplary manner of achieving separately controlled milling rates within different segments can be to vary dwell time of the ion beam at locations in the pattern. For example, in a raster pattern, the ion beam can dwell at each point in the pattern for a different length of time, allowing for fine control of the amount of material removed at that point within the pattern (and the segment). As another example, the number of passes of the ion beam across a line of the pattern within a segment can be increased or decreased to remove more or less material along that portion of the segment. As yet another example, the ion beam can be configured to skip certain points in the pattern so that no or minimal material is removed from that portion of the segment.

In some embodiments, the number of segments N can be more or fewer than depicted in FIGS. 5A and 5B. For example, the number of segments can be 2, 3, 4, 6, or 10 or more. The number of segments N can be determined based on the length (e.g., length 214 of FIG. 2) of the lamella 502. For example, a longer lamella may be thinned using a larger number of segments than a shorter lamella. The number of segments N can also be determined based on the thickness (e.g., thickness 212 of FIG. 2) of the lamella. In addition, the number of segments used for the removal of one layer of material from the sample 500 can be different than the number of segments used for the removal of another layer of material from the sample 500. For example, a first layer of material can be removed using a single segment and single endpoint until a portion of the lamella 502 is about 100 nm thick, a second layer of material can be removed using three segments and three endpoints until a second portion of the lamella 502 is about 50 nm thick, and a third layer of material can be removed using five segments and five endpoints until a third portion of the lamella 502 is less than about 15 nm thick. It is contemplated that various combinations of number of segments and number of layers removed can be used when thinning the lamella 502 to a suitable thickness. In some embodiments, each subsequent layer of material removed can include milling segments for smaller portion of the segment milled to remove the previous layer. For example, a first layer can be milled within a single segment, then a second layer can be milled for five segments that span a slightly smaller portion of the single segment. In some embodiments, the ion beam can have a different characteristic beam energy for each layer of material removal. For example, the ion beam can have a beam energy of 30 kV when removing the first layer of material and have a beam energy of 2 kV when removing the second layer and the third layer.

In some embodiments, segments can be the same size or different sizes along the length of the lamella 502. As shown in FIGS. 5A and 5B, the segments 504-512 divide the portion of the lamella 502 into five equal length segments. In some examples, the segments can have unequal widths. In particular, the segments closest to the edges of the lamella 502 may be larger than the segments in the center of the lamella 502 to account for a width of the ion beam. For example, segment 1 504 and segment N 512 may be larger than the width of segments 506-510 by a value corresponding to the width of the ion beam. In some embodiments, the segments can be arranged adjacent to one another over the portion of the lamella 502 being thinned. In other embodiments, a portion of each segment may overlap with an adjacent portion.

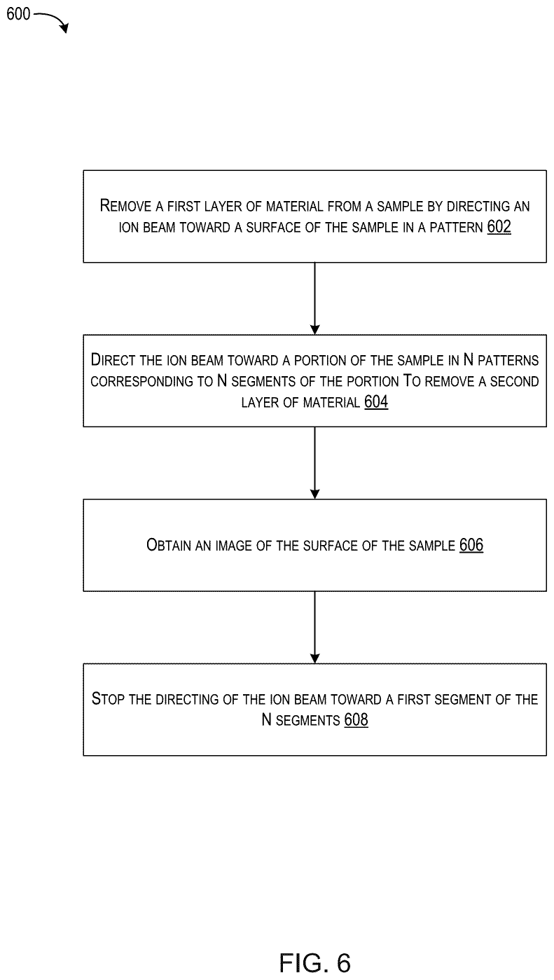

FIG. 6 is a flow diagram of an example process 600 for operating a dual beam charged particle microscope system to prepare a sample using a plurality of endpoints, according to some embodiments. The dual beam charged particle microscope system may be an example of other charged particle microscope systems described herein, including system 100 of FIG. 1. The charged particle microscope system can include a computer system (e.g., system controller 119 of FIG. 1) configured to carry out the operations of process 600. For example, a computer system may be configured to adjust the parameters of the electron beam (e.g., accelerating potential, beam focus parameters, beam current, beam deflection, etc.), the ion beam (e.g., accelerating potential, beam focus parameters, ion species selection, beam current, etc.), the milling patterns (e.g., raster), the number of segments (e.g., 1, 5, N), the scanning/imaging parameters for SEM mode (e.g., sweep time, dwell time, etc.), activation/deactivation of both the electron beam and the ion beam (or additional beams, e.g., laser beams, present in multiple beam systems), detector settings (e.g., biasing voltage, collector grid voltage, etc.), and other suitable parameters for the operation of such a microscopy system. The computer system may also be configured to analyze images obtained using the microscopy system to identify structures and/or features of interest in a sample being milled and compare those structures with desired endpoints to control the milling according to the operations of process 600. The sample may be an example of any of the samples described herein, including sample 200 of FIG. 2 and sample 400 and sample 500 of FIGS. 4A and 5A.

The process 600 can begin at block 602, with removing a first layer of material from a sample by directing an ion beam toward a surface of the sample in a pattern. The first layer can be removed from a segment of the sample, for example segment 404 of FIG. 4. The ion beam can be directed toward the surface of the sample in a raster pattern or other suitable pattern to remove material from the surface. The surface of the sample from which material is removed may be referred to as the working surface or cutface (e.g., cutface 410 of FIG. 4B) of the sample. The beam path of the ion beam may be substantially parallel to the cutface.

At blocks 604-608, a second layer of material can be removed from the segment. The second layer can be removed so that the thickness of a portion of the segment is reduced. For example, a portion of segment 404 of FIG. 4 can be further thinned to reduce the thickness of lamella 402. At block 604, the ion beam can be directed toward the portion of the segment in N patterns corresponding to N segments of the portion (e.g., segments 504-512 of FIG. 5A). The N segments can each be smaller than the segment for the first layer (e.g., the N segments may span a smaller portion of the lamella than the segment for the first layer).

At block 606, dual beam charged particle microscope system can obtain an image of the surface of the sample. The image can show a first segment of the N segments of the sample. For example, the image can be an image of the cutface 530 shown in FIG. 5B. The image can show one or more structures of the sample for each segment. In some embodiments, the image can show a view of a first structure of a plurality of structures (e.g., structures 524 of FIG. 5B) within the first segment (e.g., segment 3 508 of FIG. 5B). In some embodiments, the image can be obtained using an electron beam of the dual beam charged particle microscope system. The electron beam can be directed at the surface of the sample to image the cutface. In some embodiments, the ion beam may be used to obtain the image.

At block 608, dual beam charged particle microscope system can stop the directing of the ion beam toward the first segment of the N segments. Stopping the ion beam for the first segment may be based on the image. In some embodiments, stopping the directing of the ion beam can include comparing the image to an endpoint to the first segment of the sample. The endpoint can be characterized by a desired structure having one or more parameters. For example, the desired structure can be an ideal device feature (e.g., gate fin of a FET) for a particular manufacturing specification of the devices in the sample. The desired structure can then include dimensions, profile, pitch, or other suitable parameters for comparison in image analysis. In some embodiments, comparing the image to the endpoint can include comparing the view of the first structure to the desired structure of the endpoint. If the parameter(s) (e.g., dimensions, profile, pitch, etc.) match (e.g., are equal within some desired tolerance), then the ion beam can be stopped for the first segment.

In some embodiments, removing the second layer of material can also include continuing to direct the ion beam toward the remaining segments, obtaining an additional image of the surface of the sample, and then stopping the ion beam for a second segment of the remaining segments based on a comparison of the image and an additional endpoint. In this way, each segment of the N segments can be thinned until each segment reaches the desired endpoint. The lamella can then have the desired thickness across its length that is suitable for subsequent use (e.g., as a sample for scanning transmission electron microscopy). In some embodiments, the endpoints for each segment may be the same or may be different from one another.

In some embodiments, additional layers of material can be removed according to the operations of blocks 604-608 using more, fewer, or the same number of segments. For example, a third layer of material can be removed from the segment so that the thickness of an additional portion of the segment is further reduced. The ion beam can be directed toward the additional portion in M patterns, an additional image of the surface of the sample can be obtained, and the ion beam can be stopped for a second segment of the M segments based on a comparison of the additional image with an endpoint corresponding to the second segment.

In some embodiments, the ion beam can be set to different energies for each layer removed. For example, the first layer can be removed with the ion beam set to a first energy (e.g., 30 kV) and the second layer can be removed using the N segments with the ion beam set to a second energy (e.g., 2 kV) different from the first energy. In some embodiments, the ion beam can be configured to vary its energy or dwell time within a pattern to remove more or less material at different positions within each segment.

In some embodiments, the number of segments N can be based in part on the thickness of the sample after the removal of the first layer of material. The number of segments N can also be based on the desired thickness of the sample at the end of the removal of the second layer of material. In various embodiments, N may be a predetermined number, may be based in part on a length (e.g., length 214 of FIG. 2) of the portion of the segment, or may be based in part on a material of the sample.

In some embodiments, the N segments may be adjacent and non-overlapping. In other embodiments, one segment may overlap with a portion of another segment of the N segments. In some embodiments, each segment may have the same width or have different widths. In some embodiments, some of the segments may be wider than the other segments. For example, in some embodiments, a first segment (e.g., segment 1 504 of FIG. 5A) and a final segment (e.g., segment N 512 of FIG. 5A) of the N segments can have an extended width characterized by a default width of the N patterns and a beam width of the ion beam.

In some embodiments, the thickness of the sample within each segment can be the same as or different from the thickness of the sample for any of the other segments. For example, a first segment of the N segments can be milled to remove a layer of the sample until the endpoint is reached for that segment and the thickness of that segment is reduced. A second segment of the N segments can be milled to remove a layer of the sample until the endpoint is reached for that second segment and the thickness of that second segment is reduced further than the thickness of the first segment.

In some embodiments, stopping the directing of the ion beam toward the sample based on the image can occur after the ion beam begins removing a third or subsequent layer from the sample. For example, after removing the second layer and obtaining an image of the sample, the ion beam can remove a third layer from the sample. Based on the comparison of the image and the endpoint, the ion beam can be stopped from milling the sample after the third or subsequent layer have been removed from the sample.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on dual beam (e.g., electron and ion beams) microscopy systems, these are meant as non-limiting, illustrative embodiments. Embodiments of the present disclosure are not limited to such materials, but rather are intended to address charged particle beam systems for which a wide array of particles can be applied to imaging, microanalysis, and/or processing of materials on an atomic scale. Such particles may include, but are not limited to, electrons, ions, or photons in TEM systems, SEM systems, STEM systems, ion beam systems, and/or particle accelerator systems.

Some embodiments of the present disclosure include a system including one or more data processors and/or logic circuits. In some embodiments, the system includes a non-transitory computer readable storage medium containing instructions (e.g., executable instructions, one or more computer programs, or one or more applications) which, when executed on the one or more data processors, cause the one or more data processors to perform part or all of one or more methods and/or part or all of one or more processes and workflows disclosed herein. Some embodiments of the present disclosure include a computer-program product tangibly embodied in a non-transitory machine-readable storage medium, for example, in the form of a computer program including a plurality of instructions executable by one or more processors. The instructions can be configured to cause one or more data processors to perform part or all of one or more methods and/or part or all of one or more processes disclosed herein, including, for example, process 600 of FIG. 6.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property or numerical value within which the deviation has little to no influence of the corresponding function, property, or attribute of the structure being described. In an illustrated example, where a dimensional parameter is described as “substantially equal” to another dimensional parameter, the term “substantially” is intended to reflect that the two dimensions being compared can be unequal within a tolerable limit, such as a fabrication tolerance. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For dimensional values, such as diameters, lengths, widths, or the like, the term “about” can be understood to describe a deviation from the stated value of up to +10%. For example, a dimension of “about 15 nm” can describe a dimension from 13.5 nm to 16.5 nm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims.

Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

Examples of inventive subject matter according to the present disclosure are described in the following enumerated paragraphs.

A1. A method comprising: removing a first layer of material from a sample by at least directing an ion beam toward a surface of the sample in a pattern, the pattern corresponding to a segment of the sample, removing, after the first layer is removed, a second layer of material from the segment such that a thickness of at least a portion of the segment is reduced, the second layer removed by at least: directing the ion beam toward the portion of the sample in N patterns corresponding to N segments of the portion, each of the N segments being smaller than the portion of the sample, obtaining an image of the surface of the sample, the image showing at least a first segment of the N segments of the sample, and stopping the directing of the ion beam toward the first segment of the N segments, the stopping based on the image.

A2. The method of paragraph A1, wherein stopping the directing of the ion beam based on the image comprises comparing the image to an endpoint, the endpoint corresponding to the first segment of the sample.

A2.1. The method of paragraph A2, wherein the sample comprises a plurality of structures, wherein the image comprises a view of a first structure of the plurality of structures located within the first segment, wherein the endpoint is characterized by a desired structure, and wherein comparing the image to the endpoint comprises comparing the view of the first structure of the plurality of structures to the desired structure of the endpoint.

A3. The method of any of paragraphs A1-A2.1, wherein removing the second layer of material from the segment further comprises: continuing directing the ion beam toward a remaining portion of the sample away from the first segment, the remaining portion corresponding to remaining segments of the N segments exclusive of the first segment, obtaining an additional image of the surface of the sample, the additional image showing the remaining segments of the sample, and stopping the directing of the ion beam toward a second segment of the remaining segments, the stopping based on comparing the additional image to an additional endpoint.

A3.1 The method of paragraph A3, wherein the additional endpoint is different from the endpoint.

A4. The method of any of paragraphs A1-A3.1, further comprising: removing, after the second layer is removed, a third layer of material from the segment such that the thickness of an additional portion of the segment is further reduced, the third layer removed by at least: directing the ion beam toward the additional portion in M patterns corresponding to M segments of the additional portion, M being greater than N, and each of the M segments being smaller than each of the N segments, obtaining an additional image of the surface of the sample, the additional image showing the M segments of the sample, and stopping the directing of the ion beam toward a second segment of the M segments, the stopping based on the additional image.

A5. The method of any of paragraphs A1-A4, wherein removing the first layer of material occurs with the ion beam set to a first energy, and wherein removing the second layer of material using the N patterns occurs with the ion beam set to a second energy different from the first energy.

A6. The method of any of paragraphs A1-A5, wherein N is based in part on the thickness of the sample after the removal of the first layer of material.

A7. The method of any of paragraphs A1-A6, wherein N is based in part on a width of the portion of the segment.

A8. The method of any of paragraphs A1-A7, wherein N is based in part on a material of the sample.

A9. The method of any of paragraphs A1-A8, wherein N is a predetermined number.

B1. A system comprising: a vacuum chamber, a sample stage disposed in the vacuum chamber and configured to receive a sample in the vacuum chamber, an ion beam column configured to provide an ion beam into the vacuum chamber, and a controller comprising one or more processors and one or more memories storing computer-executable instructions that, when executed by the one or more processors, cause the system to: remove a first layer of material from the sample by at least directing the ion beam toward a surface of the sample in a pattern, the pattern corresponding to a segment of the sample, remove, after the first layer is removed, a second layer of material from the segment such that a thickness of at least a portion of the segment is reduced, the second layer removed by at least: directing the ion beam toward the portion of the sample in N patterns corresponding to N segments of the portion, each of the N segments being smaller than the portion of the sample, obtaining an image of the surface of the sample, the image showing at least a first segment of the N segments of the sample, and stopping the directing of the ion beam toward the first segment of the N segments, the stopping based on the image.

B2. The system of paragraph B1, wherein stopping the directing of the ion beam based on the image comprises comparing the image to an endpoint, the endpoint corresponding to the first segment of the sample.

B2.1. The system of paragraph B2, wherein the sample comprises a plurality of structures, wherein the image comprises a view of a first structure of the plurality of structures located within the first segment, wherein the endpoint is characterized by a desired structure, and wherein comparing the image to the endpoint comprises comparing the view of the first structure of the plurality of structures to the desired structure of the endpoint.

B3. The system of any of paragraphs B1-B2.1, wherein N is based in part on the thickness of the sample after the removal of the first layer of material.

B4. The system of any of paragraphs B1-B3, wherein the N segments are adjacent and non-overlapping.

B5. The system of any of paragraphs B1-B4, wherein a first segment of the N segments overlaps with a portion of a second segment of the N segments.

B6. The system of any of paragraphs B1-B5, wherein each of the N segments is the same width.

B7. The system of any of paragraphs B1-B6, wherein a first segment of the N segments and a final segment of the N segments each comprise a corresponding extended width characterized by (i) a default width of the N patterns and (ii) a beam width of the ion beam.

B8. The system of any of paragraphs B1-B7, further comprising an electron beam column configured to provide an electron beam into the vacuum chamber, and wherein obtaining the image comprises imaging the surface of the sample with the electron beam.

C1. A non-transitory computer-readable medium comprising instructions that, when executed by a processor of a charged particle microscopy system, cause the charged particle microscopy system to: thin a sample to a first thickness by at least using an ion beam to remove a first layer of material from a surface of the sample, the removal of the first layer of material stopped based on an image of the surface of the sample, and thin the sample by at least using the ion beam to remove a second layer of material from each of N segments of the surface of the sample, the removal of the second layer of material stopped in each of the N segments based on at least one additional image of the surface of the sample corresponding to each of the N segments.

C2. The non-transitory computer-readable medium of paragraph C1, wherein the removal of the first layer of material is stopped based on comparing the image to an endpoint corresponding to the surface of the sample.

C3. The non-transitory computer-readable medium of any of paragraphs C1-C2, wherein the removal of the second layer of material from each of the N segments is stopped based on comparing the at least one additional image of the surface to a corresponding endpoint for each segment of the N segments.

C4. The non-transitory computer-readable medium of any of paragraphs C1-C3, wherein the removal of the second layer of material from each of the N segments is performed sequentially.

C5. The non-transitory computer-readable medium of any of paragraphs C1-C4, wherein each of the N segments has a segment thickness after the second layer of material is removed.

C6. The non-transitory computer-readable medium of any of paragraphs C1-C5, wherein the segment thickness for each of the N segments is different.

What is claimed is:

1. A method comprising:
removing a first layer of material from a sample by at least directing an ion beam toward a surface of the sample in a pattern, the pattern corresponding to a segment of the sample;
removing, after the first layer is removed, a second layer of material from the segment such that a thickness of at least a portion of the segment is reduced, the second layer removed by at least:
directing the ion beam toward the portion of the sample in N patterns corresponding to N segments of the portion, each of the N segments being smaller than the portion of the sample;
obtaining an image of the surface of the sample, the image showing at least a first segment of the N segments of the sample; and
stopping the directing of the ion beam toward the first segment of the N segments, the stopping based on the image.

2. The method of claim 1, wherein stopping the directing of the ion beam based on the image comprises comparing the image to an endpoint, the endpoint corresponding to the first segment of the sample.

3. The method of claim 2, wherein the sample comprises a plurality of structures, wherein the image comprises a view of a first structure of the plurality of structures located within the first segment, wherein the endpoint is characterized by a desired structure, and wherein comparing the image to the endpoint comprises comparing the view of the first structure of the plurality of structures to the desired structure of the endpoint.

4. The method of claim 1, wherein removing the second layer of material from the segment further comprises:
continuing directing the ion beam toward a remaining portion of the sample away from the first segment, the remaining portion corresponding to remaining segments of the N segments exclusive of the first segment;
obtaining an additional image of the surface of the sample, the additional image showing the remaining segments of the sample; and
stopping the directing of the ion beam toward a second segment of the remaining segments, the stopping based on comparing the additional image to an additional endpoint.

5. The method of claim 4, wherein the additional endpoint is different from the endpoint.

6. The method of claim 1, further comprising:
removing, after the second layer is removed, a third layer of material from the segment such that the thickness of an additional portion of the segment is further reduced, the third layer removed by at least:
directing the ion beam toward the additional portion in M patterns corresponding to M segments of the additional portion, M being greater than N, and each of the M segments being smaller than each of the N segments;
obtaining an additional image of the surface of the sample, the additional image showing the M segments of the sample; and
stopping the directing of the ion beam toward a second segment of the M segments, the stopping based on the additional image.

7. The method of claim 1, wherein removing the first layer of material occurs with the ion beam set to a first energy, and wherein removing the second layer of material using the N patterns occurs with the ion beam set to a second energy different from the first energy.

8. The method of claim 1, wherein N is based in part on the thickness of the sample after the removal of the first layer of material.

9. The method of claim 1, wherein N is based in part on a width of the portion of the segment.

10. The method of claim 1, wherein N is based in part on a material of the sample.

11. The method of claim 1, wherein N is a predetermined number.

12. A system comprising:
a vacuum chamber;
a sample stage disposed in the vacuum chamber and configured to receive a sample in the vacuum chamber;
an ion beam column configured to provide an ion beam into the vacuum chamber; and
a controller comprising one or more processors and one or more memories storing computer-executable instructions that, when executed by the one or more processors, cause the system to:
remove a first layer of material from the sample by at least directing the ion beam toward a surface of the sample in a pattern, the pattern corresponding to a segment of the sample;
remove, after the first layer is removed, a second layer of material from the segment such that a thickness of at least a portion of the segment is reduced, the second layer removed by at least:
directing the ion beam toward the portion of the sample in N patterns corresponding to N segments of the portion, each of the N segments being smaller than the portion of the sample;
obtaining an image of the surface of the sample, the image showing at least a first segment of the N segments of the sample; and
stopping the directing of the ion beam toward the first segment of the N segments, the stopping based on the image.

13. The system of claim 12, wherein stopping the directing of the ion beam based on the image comprises comparing the image to an endpoint, the endpoint corresponding to the first segment of the sample.

14. The system of claim 13, wherein the sample comprises a plurality of structures, wherein the image comprises a view of a first structure of the plurality of structures located within the first segment, wherein the endpoint is characterized by a desired structure, and wherein comparing the image to the endpoint comprises comparing the view of the first structure of the plurality of structures to the desired structure of the endpoint.

15. The system of claim 12, wherein N is based in part on the thickness of the sample after the removal of the first layer of material.

16. The system of claim 12, wherein the N segments are adjacent and non-overlapping.

17. The system of claim 12, wherein a first segment of the N segments overlaps with a portion of a second segment of the N segments.

18. The system of claim 12, wherein each of the N segments is the same width.

19. The system of claim 12, wherein a first segment of the N segments and a final segment of the N segments each comprise a corresponding extended width characterized by (i) a default width of the N patterns and (ii) a beam width of the ion beam.

20. The system of claim 12, further comprising an electron beam column configured to provide an electron beam into the vacuum chamber, and wherein obtaining the image comprises imaging the surface of the sample with the electron beam.
